(19) United States
(12) Patent Application Publication
(10) Pub. No.: US 2025/0246549 A1
(43) Pub. Date: Jul. 31, 2025

(54) SEMICONDUCTOR INTEGRATED CIRCUIT DEVICE

(71) Applicant: Nuvoton Technology Corporation Japan, Kyoto (JP)

(72) Inventors: Misao NAKANO, Osaka (JP); Takeo NAKAMURA, Kyoto (JP)

(21) Appl. No.: 19/082,833

(22) Filed: Mar. 18, 2025

Related U.S. Application Data
(63) Continuation of application No. PCT/JP2023/034737, filed on Sep. 25, 2023.

(30) Foreign Application Priority Data
Sep. 27, 2022 (JP) 2022-153465

(51) Int. Cl. H01L 23/528

(52) U.S. Cl. CPC H01L 23/5286; H01L 23/528; H01L 23/5283

(57) ABSTRACT

A semiconductor integrated circuit device includes: standard cell rows each of which includes standard cells that are arranged in an X direction and a power supply wire that extends in the X direction and supplies power to the standard cells; strap power supply wires that extend in a Y direction; supplementary strap power supply wires that extend in the Y direction and are each connected to each of the power supply wires; and switch cells arranged at intersections between the strap power supply wires and the power supply wires. The standard cell rows include a standard cell row in which no switch cell is disposed at one or more positions corresponding to, among a plurality of standard cell columns, one or more standard cell columns other than standard cell columns located at both ends of the plurality of standard cell columns.

### CROSS REFERENCE TO RELATED APPLICATION(S)

This is a continuation application of PCT International Patent Application No. PCT/JP2023/034737 filed on Sep. 25, 2023, designating the United States of America, which is based on and claims priority of Japanese Patent Application No. 2022-153465 filed on Sep. 27, 2022. The entire disclosures of the above-identified applications, including the specifications, drawings and claims are incorporated herein by reference in their entirety.

### FIELD

The present disclosure relates to a semiconductor integrated circuit device.

### BACKGROUND

For realizing low power consumption of a semiconductor integrated circuit device, providing, to each of standard cell columns, a switch that switches between supply and interruption of power to the standard cell column so as to interrupt power supply to a standard cell column that does not need to be supplied with power has been considered. Each of standard cells is supplied with power from a strap power supply wire through a switch and a standard cell power supply wire.

However, when a switch is provided to each of standard cell power supply wires, the area of a circuit block that includes each of the standard cell columns becomes large. Then, Patent Literature (PTL) 1 discloses a semiconductor integrated circuit device that can suppress the number of switches provided.

### CITATION LIST

### Patent Literature

PTL 1: WO2017/208887

### SUMMARY

### Technical Problem

Since various wires are provided in a semiconductor integrated circuit device, ease of wiring is desired to be improved. However, PTL 1 does not disclose improving ease of wiring.

Then, the present disclosure provides a semiconductor integrated circuit device that can realize low power consumption and improve ease of wiring.

### Solution to Problem

A semiconductor integrated circuit device according to an aspect of the present disclosure includes: a plurality of standard cell rows each of which includes a plurality of standard cells that are arranged in a first direction and a power supply wire that extends in the first direction and supplies power to the plurality of standard cells; a plurality of strap power supply wires that extend in a second direction above a plurality of power supply wires each of which is the power supply wire, the second direction being orthogonal to the first direction; a plurality of supplementary strap power supply wires that extend in the second direction above the plurality of power supply wires and are each connected to each of the plurality of power supply wires; and a plurality of first switch cells arranged at intersections between the plurality of strap power supply wires and the plurality of power supply wires, each of the plurality of first switch cells being configured to switch between electrical connection and disconnection between the strap power supply wire and the power supply wire at the intersection at which the first switch cell is arranged, according to a control signal. The plurality of standard cell rows are arranged in the second direction to form a plurality of standard cell columns, and the plurality of standard cell rows include a first standard cell row in which none of the plurality of first switch cells are arranged at one or more positions corresponding to, among the plurality of standard cell columns, one or more standard cell columns other than standard cell columns located at both ends of the plurality of standard cell columns.

### Advantageous Effects

According to an aspect of the present disclosure, a semiconductor integrated circuit device that can realize low power consumption and improve ease of wiring can be achieved.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view of the configuration of a semiconductor integrated circuit device according to an embodiment.

FIG. 2 is a cross-sectional view of the semiconductor integrated circuit device taken at line II-II in FIG. 1.

FIG. 3 is a first plan view for describing an arrangement of switch cells in the semiconductor integrated circuit device according to the embodiment.

FIG. 4 is a second plan view for describing an arrangement of switch cells in the semiconductor integrated circuit device according to the embodiment.

FIG. 5 is a plan view of the configuration of a semiconductor integrated circuit device according to Variation 1 of the embodiment.

FIG. 6 is a plan view of the configuration of a semiconductor integrated circuit device according to Variation 2 of the embodiment.

FIG. 7 is a plan view of the configuration of a semiconductor integrated circuit device according to Variation 3 of the embodiment.

### DESCRIPTION OF EMBODIMENT

Hereinafter, the embodiment and the like are described in detail with reference to the Drawings.

It should be noted that each of the embodiment and the like described below shows a general or specific example. The numerical values, constituent elements, the arrangement and connection of the constituent elements, etc. shown in the following embodiment and the like are mere examples, and therefore do not limit the scope of the present disclosure. Moreover, among the constituent elements in the following embodiment and the like, those not recited in the independent claim are described as arbitrary constituent elements.

Furthermore, respective drawings are schematic diagrams and are not necessarily precise illustrations. Accordingly, for example, the scaling or the like depicted in the Drawings is not necessarily accurate. Furthermore, components that are essentially the same share like reference signs in the Drawings, and overlapping explanations thereof are omitted or simplified.

Moreover, in the Specification, a term indicating a relationship between elements, such as orthogonal; a term indicating the shape of an element, such as zigzag; a numerical value; and a numerical range are not intended to exactly represent the meaning thereof, and may include a range substantially the same as the meaning thereof, for example, may include a deviation of a few percent (e.g., approx. 10 percent).

Furthermore, in the Specification, ordinal numbers, such as “first” and “second”, do not mean the number or order of constituent elements unless otherwise specified, and are used for the purpose of avoiding confusion of constituent elements of the same type and differentiating them.

### Embodiment

### [1. Configuration of Semiconductor Integrated Circuit Device]

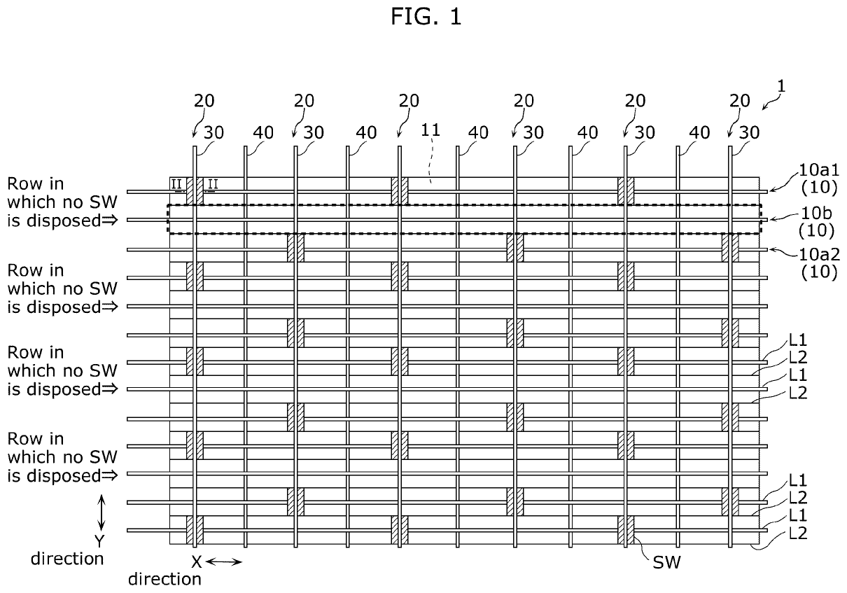

Hereinafter, a semiconductor integrated circuit device according to the present embodiment is described with reference to FIG. 1 to FIG. 4. FIG. 1 is a plan view illustrating the configuration of semiconductor integrated circuit device 1 according to the present embodiment. In FIG. 1, a simplified layout pattern in a circuit block that selectively interrupt power supply is illustrated. It should be noted that although switch cell SW or the like is illustrated with hatching for illustrative purposes in each drawing, it is not intended to indicate the cross-section of switch cell SW or the like. Moreover, in FIG. 1, an area where standard cell 11 is disposed is indicated by the reference sign 11.

As illustrated in FIG. 1, semiconductor integrated circuit device 1 includes a plurality of standard cell rows 10, a plurality of strap power supply wires 30, a plurality of supplementary strap power supply wires 40, and a plurality of switch cells SW. The constituent elements of semiconductor integrated circuit device 1 are arranged on a substrate (not illustrated), for example.

Each of the plurality of standard cell rows 10 includes a plurality of standard cells 11 that are arranged in an X direction (a first direction) and power supply wire L1 and ground power supply wire L2 that extend in the X direction (i.e., the direction in which the plurality of standard cells 11 are arranged). Moreover, the plurality of standard cell rows 10 are arranged in a Y direction to form a plurality of standard cell columns 20, the Y direction being orthogonal to the X direction.

Standard cell 11 is a basic circuit element that has a function of an inverter or a logic circuit, for example, and a semiconductor integrated circuit device that realizes a predetermined function can be manufactured by arranging and wiring standard cells 11 in combination. Each of standard cells 11 includes, for example, an N-type region in which a P-type metal oxide semiconductor (PMOS) transistor is formed and a P-type region in which an N-type MOS (NMOS) transistor is formed. Moreover, in each of standard cells 11, the N-type region and the P-type region may be arranged in the Y direction, for example. It should be noted that the internal structure of standard cell 11 is not illustrated.

Ground power supply wire L2 is disposed between standard cell rows 10. Power supply wire L1 is connected to each of the plurality of standard cells 11 arranged in standard cell row 10 and supplies power (power supply potential (VDD)) to each of the plurality of standard cells 11. Moreover, ground power supply wire L2 is connected to each of the plurality of standard cells 11 arranged in standard cell row 10 and supplies ground potential (VSS) to each of the plurality of standard cells 11.

In the present embodiment, the plurality of standard cell rows 10 include standard cell rows 10a1 and 10a2 (second standard cell rows) in each of which switch cell SW is disposed and standard cell row 10b (“row in which no SW is disposed” in FIG. 1, that is, first standard cell row) in which no switch cell SW is disposed. It should be noted that it is sufficient if at least one standard cell row 10b is disposed.

It should be noted that one standard cell row 10 is a range in which a plurality of sets each of which includes two standard cells 11 arranged longitudinally (in the Y direction) are arranged laterally (in the X direction). For example, standard cell row 10b is a range indicated by a broken line frame.

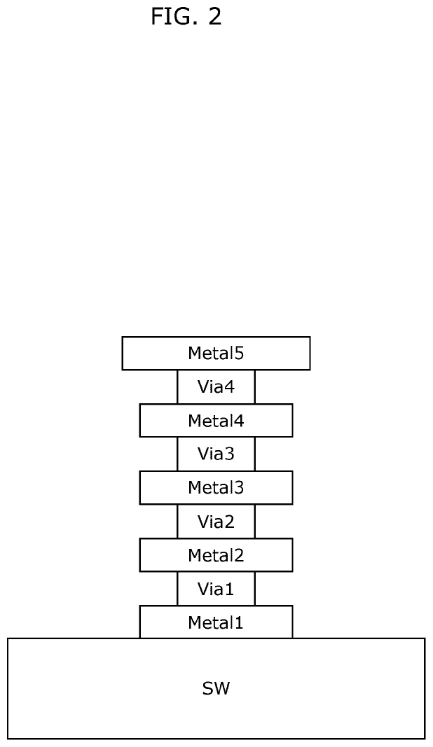

Strap power supply wire 30 is disposed to extend in the Y direction. Strap power supply wire 30 may be disposed above standard cell column 20 and power supply wires L1, for example. Moreover, strap power supply wire 30 is connected to, through a via structure (see FIG. 2), an input terminal (not illustrated) of each of switch cells SW arranged below strap power supply wire 30. Furthermore, in plan view, strap power supply wire 30 is disposed to overlap (to be electrically connected to) each of switch cells SW arranged in standard cell column 20.

Supplementary strap power supply wire 40 is disposed to extend in the Y direction. Supplementary strap power supply wire 40 may be disposed above standard cell column 20 and power supply wires L1, for example. Supplementary strap power supply wire 40 is connected to, through a via structure (not illustrated), power supply wires L1 arranged below supplementary strap power supply wire 40. Moreover, in plan view, supplementary strap power supply wire 40 is positioned not to overlap any of switch cells SW. For example, supplementary strap power supply wire 40 and strap power supply wire 30 are alternately arranged in the X direction.

Supplementary strap power supply wire 40 is connected to power supply wires L1 arranged in respective standard cell rows 10a1, 10a2, and 10b. In other words, supplementary strap power supply wire 40 is connected to power supply wire L1 in a standard cell row in which switch cell SW is disposed and power supply wire L1 in a standard cell row in which no switch cell SW is disposed. For example, each of the plurality of supplementary strap power supply wires 40 is connected to each of the plurality of power supply wires L1.

Supplementary strap power supply wire 40 and strap power supply wire 30 are not electrically connected to each other.

Switch cell SW controls whether to interrupt power supply to standard cell 11. Switch cell SW is disposed at an intersection between strap power supply wire 30 and power supply wire L1 in plan view, and configured to switch between electrical connection and disconnection between strap power supply wire 30 and power supply wire L1 according to a control signal. In other words, switch cell SW switches between conduction and non-conduction between strap power supply wire 30 and power supply wire L1. For example, switch cells SW are arranged at intersections between any one of the plurality of strap power supply wires 30 and a wiring set of N (N is an integer greater than or equal to 1) power supply wires L1 among the plurality of power supply wires L1, and each of switch cells SW is configured to switch between electrical connection and disconnection between strap power supply wire 30 and power supply wire L1 belonging to the wiring set at the intersection at which switch cell SW is arranged, according to a control signal. The control signal is, for example, inputted from a control device that controls interruption of power supply.

Switch cell SW includes an input terminal to which strap power supply wire 30 is connected and a terminal that receives a control signal for switching between conduction and non-conduction. Moreover, switch cell SW is a semiconductor switch of which source is connected to the input terminal (i.e., strap power supply wire 30), of which drain is connected to power supply wire L1, and of which gate is connected to the terminal that receives a control signal. Conduction and non-conduction between strap power supply wire 30 and power supply wire L1 are switched according to High/Low of a control signal.

It should be noted that the plurality of switch cells SW are not arranged at all of the intersections between the plurality of strap power supply wires 30 and the plurality of power supply wires L1. Switch cell SW is an example of a first switch cell.

In the above-described semiconductor integrated circuit device 1, power is supplied to standard cell row 10b through any one of the plurality of supplementary strap power supply wires 40. For example, when power is supplied to standard cells 11 in standard cell row 10b, switch cell SW in a standard cell row (e.g., standard cell row 10a1 or 10a2) that is close to (e.g., adjacent to) standard cell row 10b is turned on to supply power to power supply wire L1 of the standard cell row.

Since power supply wire L1 is connected to supplementary strap power supply wire 40 through a via structure, power is also supplied to supplementary strap power supply wire 40. In other words, power is supplied along supplementary strap power supply wire 40. Since supplementary strap power supply wire 40 is also connected to power supply wire L1 of standard cell row 10b through a via structure, power supply wire L1 of standard cell row 10b is supplied with power through supplementary strap power supply wire 40 from power supply wire L1 of the standard cell row in which switch cell SW is disposed.

Thus, standard cells 11 in standard cell row 10b in which no switch cell SW is disposed are supplied with power through strap power supply wire 30, switch cell SW, power supply wire L1 of the standard cell row in which switch cell SW is disposed, and supplementary strap power supply wire 40. Moreover, in the present embodiment, standard cell row 10b is supplied with power through only supplementary strap power supply wire 40.

Next, the cross-sectional structure (layered structure) of semiconductor integrated circuit device 1 is described with reference to FIG. 2. FIG. 2 is a cross-sectional view of semiconductor integrated circuit device 1 taken at line II-II in FIG. 1. FIG. 2 illustrates the cross-sectional structure of a portion where switch cell SW is disposed.

As illustrated in FIG. 2, semiconductor integrated circuit device 1 includes, on the substrate, switch cell SW and five or more wiring layers. For example, first to fifth wiring layers (Metals 1 to 5) are formed so that the first to fifth wiring layers are layered in the stated order from the substrate. The first to fifth wiring layers are electrically connected to each other through vias (Vias 1 to 4). The first wiring layer is a wiring layer for power supply. For example, power supply wire L1 and ground power supply wire L2 are located in the first wiring layer (Metal 1). A wire (for example, power supply wire L1) in the first wiring layer is also connected to switch cell SW.

Moreover, the second and fourth wiring layers (Metals 2 and 4) are wiring layers each of which is for a signal wire that extends in the X direction. The preferential wiring direction of the second and fourth wiring layers is the X direction. Moreover, the third and fifth wiring layers (Metals 3 and 5) are wiring layers each of which is for a wire that extends in the Y direction. The preferential wiring direction of the third and fifth wiring layers is the Y direction. Strap power supply wire 30 and supplementary strap power supply wire 40 are located in any of the third and fifth wiring layers. For example, supplementary strap power supply wire 40 may be disposed below strap power supply wire 30.

Moreover, the cross-sectional structure of a portion where no switch cell SW is disposed at strap power supply wire 30 includes a wiring layer (e.g., Metal 3 or 5) for strap power supply wire 30 but does not include another wiring layer, for example. In other words, since part (e.g., the second to fourth wiring layers) of the first to fifth wiring layers shown in FIG. 2 can be omitted by reducing the number of switch cells SW provided to semiconductor integrated circuit device 1, another wire can pass straight through a portion where the part of the first to fifth wiring layers used to be located. Thus, according to semiconductor integrated circuit device 1, ease of wiring can be improved.

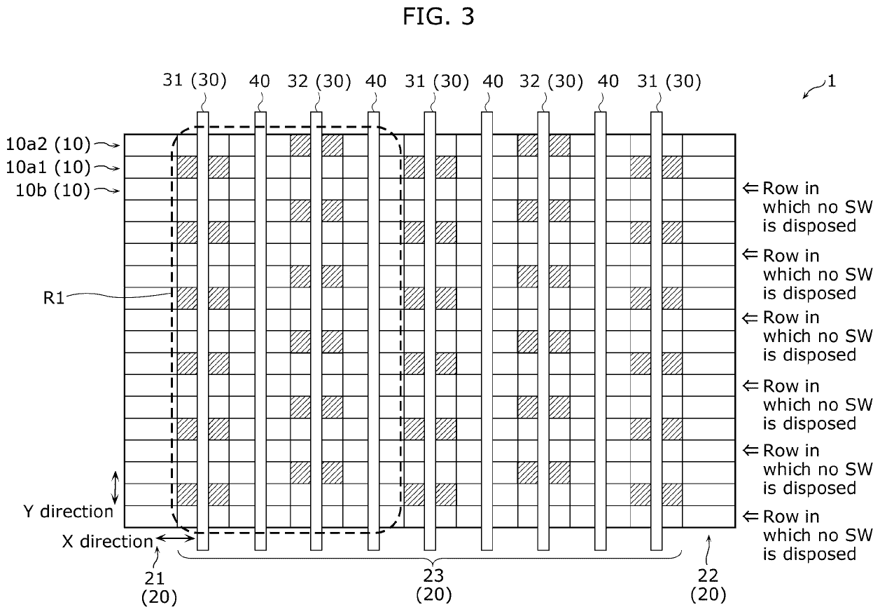

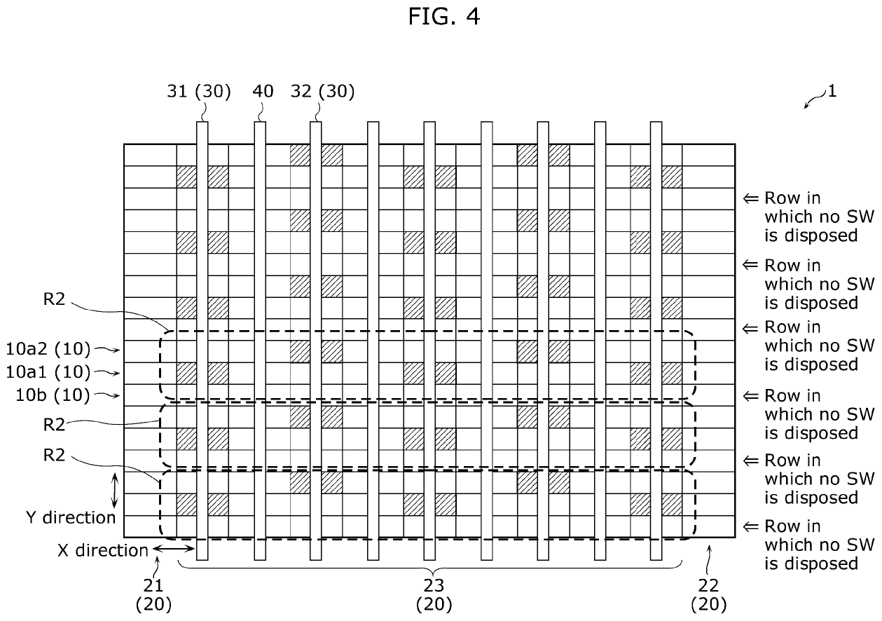

Next, arrangement positions of switch cells SW are described with reference to FIG. 3 and FIG. 4. First, an example in which an arrangement of switch cells SW is repeated in the X direction is described with reference to FIG. 3. FIG. 3 is a first plan view for describing an arrangement of switch cells SW in semiconductor integrated circuit device 1 according to the present embodiment. It should be noted that FIG. 3 is a diagram for describing that an arrangement of switch cells SW is repeated in the same pattern in the X direction, and part of the configuration shown in FIG. 1 is omitted for illustrative purposes. Moreover, FIG. 3 illustrates an example in which the number of standard cell rows 10 and the number of standard cell columns 20 are different from those shown in FIG. 1, for illustrative purposes.

As illustrated in FIG. 3, no switch cell SW is disposed in standard cell row 10b. In standard cell row 10b, no switch cell SW is disposed at one or more positions corresponding to, among the plurality of standard cell columns 20, one or more standard cell columns 20 other than standard cell columns 21 and 22 located at both ends of the plurality of standard cell columns 20 as well as positions corresponding to standard cell columns 21 and 22 located at the both ends. Standard cell row 10b is a standard cell row that includes a plurality of standard cells 11 (power supply targets) but does not include switch cell SW (a power supply source). Moreover, although standard cell row 10b is disposed between standard cell rows 10a1 and 10a2 for example, the present disclosure is not limited to this example. Furthermore, for example, standard cell rows 10b may be arranged continuously or discontinuously in the Y direction.

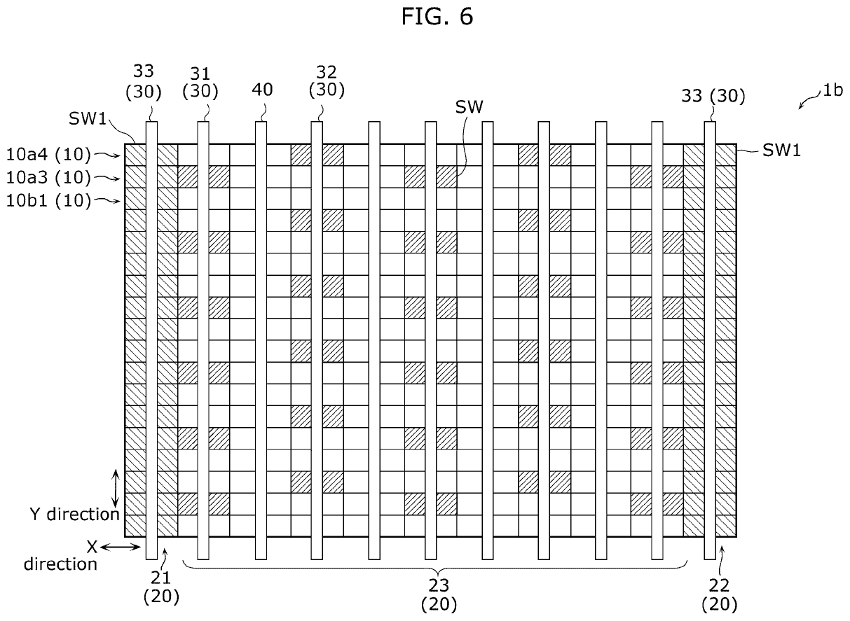

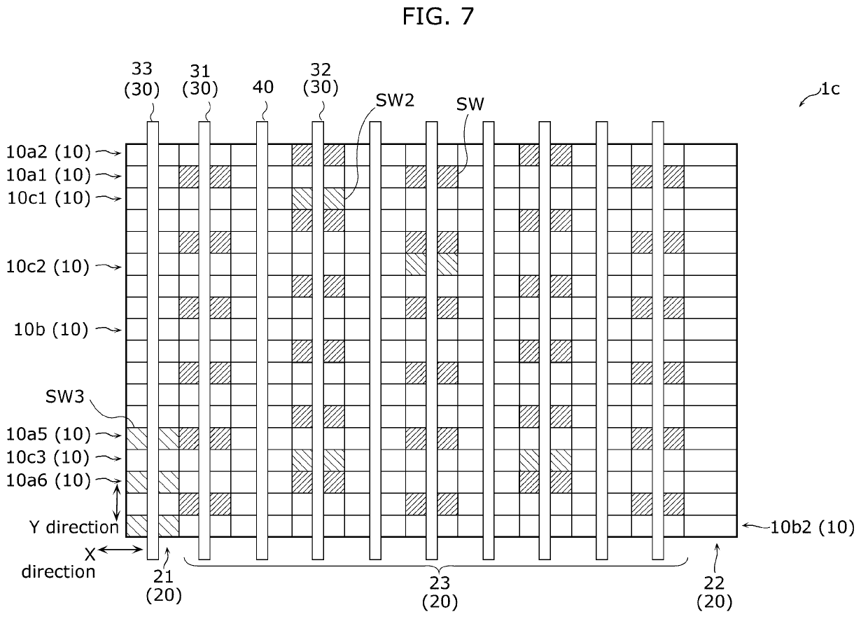

It should be noted that a configuration in which no switch cell SW is disposed at each of positions corresponding to standard cell columns 21 and 22 located at the both ends is not essential. A configuration in which at least one switch cell SW is disposed at any one of the positions corresponding to standard cell columns 21 and 22 is described later with reference to FIG. 6 and FIG. 7.

Moreover, in the present embodiment, standard cell row 10b is disposed for every three rows. Thus, standard cell rows 10b may be arranged at intervals of a predetermined number of rows so that standard cell rows 10b are evenly spaced apart from each other. It should be noted that standard cell rows 10b are not necessarily evenly spaced apart from each other, and may be arranged randomly.

Moreover, in the present embodiment, the plurality of strap power supply wires 30 include strap power supply wire 31 (a first strap power supply wire) and strap power supply wire 32 (a second strap power supply wire) that are adjacent to each other and different from each other in arrangement positions of switch cells SW in the Y direction. For example, in plan view, switch cells SW at strap power supply wires 31 and 32 are arranged in a zigzag manner. Thus, adjacent strap power supply wires 30 may be different from each other in arrangement positions of switch cells SW in the Y direction. For example, in the present embodiment, switch cells SW are not arranged at both of adjacent strap power supply wires 30 in one standard cell row 10.

Moreover, in the present embodiment, arrangement positions of switch cells SW in the X direction are the same for every two strap power supply wires 30 (every repeat unit R1 in FIG. 3). In other words, an arrangement of switch cells SW is repeated in the same arrangement pattern for every two strap power supply wires 30. In the example in FIG. 3, strap power supply wire 31 and strap power supply wire 32 are alternately arranged.

It should be noted that an arrangement of switch cells SW is not necessarily repeated in the same arrangement pattern for every two strap power supply wires 30, and may be repeated in the same arrangement pattern for every three or more strap power supply wires 30. For example, arrangement positions of switch cells SW in the X direction may be the same for every M (M is a natural number greater than or equal to 2) strap power supply wires 30 among the plurality of strap power supply wires 30.

It should be noted that at least one standard cell row 10b is included in repeat unit R1. In the example in FIG. 3, standard cell row 10 in which no switch cell SW is disposed is included in repeat unit R1. Standard cell row 10b is formed by repeatedly disposing, in the X direction, standard cell row 10 in which no switch cell SW is disposed, for every repeat unit.

Next, an example in which an arrangement of switch cells SW is repeated in the Y direction is described with reference to FIG. 4. FIG. 4 is a second plan view for describing an arrangement of switch cells SW in semiconductor integrated circuit device 1 according to the present embodiment. The configuration of semiconductor integrated circuit device 1 shown in FIG. 4 is the same as that in FIG. 3.

As illustrated in FIG. 4, in the present embodiment, the plurality of standard cell rows 10 include standard cell row 10a2 (fifth standard cell row) and standard cell row 10a1 (fourth standard cell row) that are adjacent to each other and in each of which one or more switch cells SW among the plurality of switch cells SW are arranged. The one or more switch cells SW in standard cell row 10a1 and the one or more switch cells SW in standard cell row 10a2 are different from each other in arrangement position in the X direction. For example, in plan view, switch cells SW in standard cell rows 10a1 and 10a2 are arranged in a zigzag manner. Thus, arrangement positions of switch cells SW in the X direction may be different between adjacent standard cell rows 10.

Moreover, in the present embodiment, arrangement positions of switch cells SW in the Y direction are the same for every three standard cell rows 10 (every repeat unit R2 in FIG. 4). In other words, an arrangement of switch cells SW is repeated in the same arrangement pattern for every three standard cell rows 10.

It should be noted that an arrangement of switch cells SW is not necessarily repeated in the same arrangement pattern for every three standard cell rows 10 and may be repeated in the same arrangement pattern for every two or four or more standard cell rows 10. For example, arrangement positions of switch cells SW in the X direction may be the same for every N (N is a natural number greater than or equal to 2) standard cell rows 10 among the plurality of standard cell rows 10. It should be noted that standard cell row 10b is included in every N standard cell rows 10 (i.e., repeat unit R2). In other words, standard cell rows 10b are arranged at intervals of a predetermined number of rows.

It should be noted that, although an example in which an arrangement of switch cells SW is repeated in both of the X direction and the Y direction has been described with reference to FIG. 3 and FIG. 4 in the present embodiment, it is sufficient if an arrangement of switch cells SW is repeated in at least one of the X direction or the Y direction.

### [2. Advantageous Effect, etc.]

As described above, semiconductor integrated circuit device 1 according to the present embodiment includes: a plurality of standard cell rows 10 each of which includes a plurality of standard cells 11 that are arranged in an X direction (a first direction) and power supply wire L1 that extends in the X direction and supplies power to the plurality of standard cells 11; a plurality of strap power supply wires 30 that extend in a Y direction (a second direction) above a plurality of power supply wires L1 each of which is power supply wire L1, the Y direction being orthogonal to the X direction; a plurality of supplementary strap power supply wires 40 that extend in the Y direction above the plurality of power supply wires L1 and are each connected to each of the plurality of power supply wires L1; and a plurality of switch cells SW (first switch cells) arranged at intersections between the plurality of strap power supply wires 30 and the plurality of power supply wires L1, each of the plurality of switch cells SW being configured to switch between electrical connection and disconnection between strap power supply wire 30 and power supply wire L1 at the intersection at which switch cell SW is arranged, according to a control signal. Moreover, the plurality of standard cell rows 10 are arranged in the Y direction to form a plurality of standard cell columns 20, and the plurality of standard cell rows 10 include standard cell row 10b (a first standard cell row) in which none of the plurality of switch cells SW are arranged at one or more positions corresponding to, among the plurality of standard cell columns 20, one or more standard cell columns 23 other than standard cell columns 21 and 22 located at both ends of the plurality of standard cell columns 20.

Accordingly, semiconductor integrated circuit device 1 can realize low power consumption since semiconductor integrated circuit device 1 includes switch cell SW that can switch between connection and disconnection between strap power supply wire 30 and power supply wire L1, that is, since semiconductor integrated circuit device 1 has a configuration for interrupting power supply. Moreover, in standard cell row 10b in which no switch cell SW is disposed, another wire can be easily disposed since a via structure for connecting strap power supply wire 30 and power supply wire L1 is not necessary. Accordingly, semiconductor integrated circuit device 1 can realize low power consumption and improve ease of wiring.

Moreover, in standard cell row 10b, none of the plurality of switch cells SW are arranged at positions corresponding to standard cell columns 21 and 22 located at the both ends.

Accordingly, ease of wiring can be further improved since the number of switch cells SW can be further reduced, that is, since the number of via structures can be reduced.

Moreover, standard cell row 10b is supplied with power through any one of the plurality of supplementary strap power supply wires 40. For example, the plurality of standard cell rows 10 further include standard cell row 10a1 or 10a2 (a second standard cell row) in which one or more switch cells SW among the plurality of switch cells SW are arranged at one or more positions corresponding to one or more standard cell columns 23 among the plurality of standard cell columns 20. The plurality of supplementary strap power supply wires 40 are each connected to each of power supply wires L1 arranged in standard cell row 10b and standard cell row 10a1 or 10a2 among the plurality of power supply wires L1.

Accordingly, standard cell row 10 in which no switch cell SW is disposed can also be supplied with power through supplementary strap power supply wire 40. In other words, low power consumption and ease of wiring can be improved while standard cells 11 in standard cell row 10 in which no switch cell SW is disposed are operable.

Moreover, the plurality of strap power supply wires 30 include strap power supply wire 31 (a first strap power supply wire) and strap power supply wire 32 (a second strap power supply wire) that are adjacent to each other, and the plurality of switch cells SW may have arrangement positions in the Y direction that are different between strap power supply wires 31 and 32. For example, arrangement positions of the plurality of switch cells SW in the X direction may be the same for every M (M is a natural number greater than or equal to 2) strap power supply wires 30 among the plurality of strap power supply wires 30.

Moreover, the plurality of standard cell rows 10 further include standard cell row 10a1 (a fourth standard cell row) and standard cell row 10a2 (a fifth standard cell row) in each of which different one or more first switch cells among the plurality of switch cells SW are arranged, standard cell row 10a1 and standard cell row 10a2 being adjacent to each other. Furthermore, the one or more switch cells SW arranged in standard cell row 10a1 and the one or more switch cells SW arranged in standard cell row 10a2 may be different from each other in arrangement position in the X direction. For example, arrangement positions of the plurality of switch cells SW in the Y direction may be the same for every N (N is a natural number greater than or equal to 2) standard cell rows including standard cell row 10b among the plurality of standard cell rows 10.

Accordingly, since an arrangement of switch cells SW can be arbitrarily set, switch cells SW can be arranged more freely.

### (Variation 1 of Embodiment)

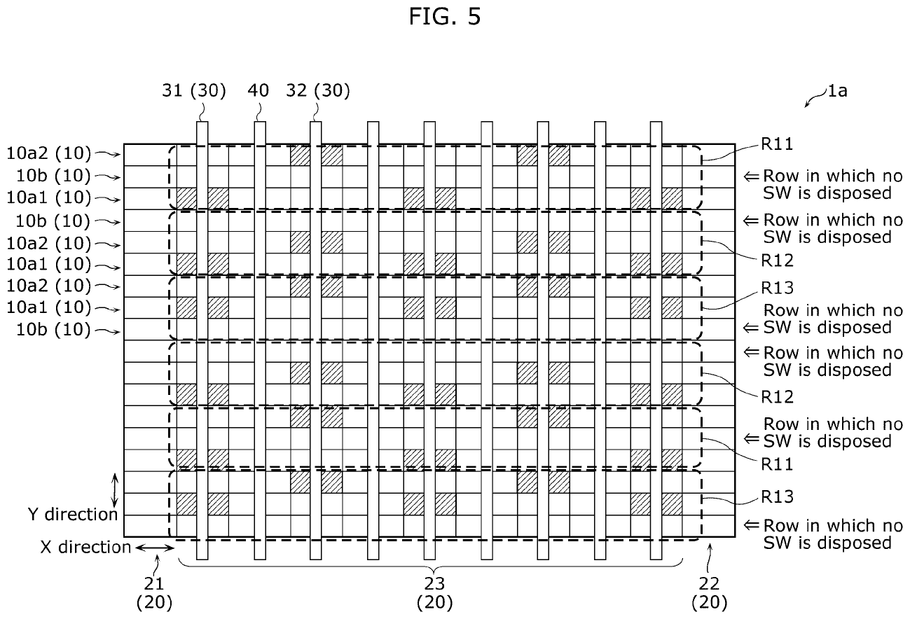

Hereinafter, a semiconductor integrated circuit device according to the present variation is described with reference to FIG. 5. FIG. 5 is a plan view of the configuration of semiconductor integrated circuit device 1a according to the present variation. It should be noted that, hereinafter, the description will focus on the difference from the embodiment, and the content that is the same as or similar to that of the embodiment is omitted or simplified. Semiconductor integrated circuit device 1a according to the present variation is different from semiconductor integrated circuit device 1 according to the embodiment in that an arrangement of switch cells SW is repeated in different patterns in the Y direction. It should be noted that, hereinafter, an example in which an arrangement of standard cell rows 10 in the Y direction is different between adjacent repeat units each of which includes three standard cell rows 10 is described.

As illustrated in FIG. 5, semiconductor integrated circuit device 1a has a configuration in which a repeat unit (each of repeat units R11, R12, and R13) includes three standard cell rows 10, and repeat units R11, R12, and R13 are arranged in the Y direction.

Each of repeat units R11, R12, and R13 is formed of a plurality of standard cell rows 10. For example, although the number of standard cell rows 10 included in one repeat unit is the same among repeat units R11, R12, and R13, the number of standard cell rows 10 included in one repeat unit may be different among repeat units R11, R12, and R13.

In the example in FIG. 5, each of repeat units R11, R12, and R13 includes one standard cell row 10a1, one standard cell row 10a2, and one standard cell row 10b, and the order of standard cell rows 10a1, 10a2, and 10b in the Y direction is different among repeat units R11, R12, and R13. Each of repeat units R11, R12, and R13 includes at least one standard cell row 10b.

It should be noted that although the arrangement order of repeat units R11, R12, and R13 is not particularly limited, the arrangement order of repeat units R11, R12, and R13 may be set so that the same repeat units are not arranged continuously in the Y direction, for example. For example, the arrangement order of repeat units R11, R12, and R13 may be randomly set so that the same repeat units are not arranged continuously in the Y direction. Moreover, although an example in which the number of standard cell rows 10 included in one repeat unit and arrangement positions of switch cells SW in standard cell row 10 are the same among repeat units R11, R12, and R13 has been described above, the number of standard cell rows 10 included in one repeat unit and arrangement positions of switch cells SW in standard cell row 10 may be different among repeat units R11, R12, and R13. Furthermore, in standard cell row 10 included in at least one of repeat units R11, R12, or R13, switch cells SW may be arranged at positions corresponding to standard cell columns 21 and 22 located at the both ends, for example.

### (Variation 2 of Embodiment)

Hereinafter, a semiconductor integrated circuit device according to the present variation is described with reference to FIG. 6. FIG. 6 is a plan view of the configuration of semiconductor integrated circuit device 1b according to the present variation. It should be noted that, hereinafter, the description will focus on the difference from the embodiment, and the content that is the same as or similar to that of the embodiment is omitted or simplified. Semiconductor integrated circuit device 1b according to the present variation is different from semiconductor integrated circuit device 1 according to the embodiment in that switch cells SW1 are arranged in both standard cell columns 21 and 22 located at the both ends. It should be noted that switch cells SW1 arranged in standard cell columns 21 and 22 located at the both ends are hatched differently from switch cells SW arranged in the embodiment or the like. Moreover, a note “a row in which no SW is disposed” is omitted in FIG. 6 and the subsequent drawing.

As illustrated in FIG. 6, semiconductor integrated circuit device 1b includes, in addition to the configuration of semiconductor integrated circuit device 1 illustrated in FIG. 3 and FIG. 4, switch cells SW1 and strap power supply wires 33 in standard cell columns 21 and 22. Regardless of whether switch cell SW is disposed at a position corresponding to any of one or more standard cell columns 23 other than standard cell columns 21 and 22, switch cells SW1 are arranged in standard cell columns 21 and 22.

Thus, in standard cell row 10b1 (first standard cell row) and standard cell rows 10a3 and 10a4 (second standard cell rows), switch cells SW1 are arranged at positions corresponding to standard cell columns 21 and 22 located at the both ends among the plurality of standard cell columns 20, in addition to switch cells SW included in semiconductor integrated circuit device 1. In other words, in standard cell row 10b1, switch cells SW1 are arranged at positions corresponding to standard cell columns 21 and 22 located at the both ends. It should be noted that switch cell SW1 has the same configuration as switch cell SW. Moreover, switch cell SW1 is an example of a second switch cell.

It should be noted that switch cells SW1 are not necessarily arranged in both standard cell columns 21 and 22, and switch cell SW1 may be disposed in one of standard cell columns 21 or 22. Moreover, switch cell SW1 is not necessarily disposed in each of the plurality of standard cell columns 20, and may be disposed in standard cell row 10b1 only, or may be disposed, in standard cell row 10b1, at a position corresponding to at least one of standard cell columns 21 or 22 located at the both ends among the plurality of standard cell columns 20, for example. Furthermore, switch cells SW1 may be arranged in standard cell columns 21 and 22 at intervals of a predetermined number of rows. It is sufficient if semiconductor integrated circuit device 1b includes at least one switch cell SW1 in somewhere in standard cell columns 21 and 22.

Strap power supply wires 33 are arranged in standard cell columns 21 and 22 so that strap power supply wires 33 extend in the Y direction. Strap power supply wires 33 may be arranged above standard cell columns 21 and 22 and power supply wires L1, for example. Moreover, strap power supply wire 33 is connected to, through a via structure (see FIG. 2), an input terminal (not illustrated) of switch cell SW1 disposed below strap power supply wire 33. Furthermore, in plan view, strap power supply wires 33 are arranged to overlap (to be electrically connected to) respective switch cells SW arranged in standard cell columns 21 and 22.

As described above, semiconductor integrated circuit device 1b according to the present variation further includes, in standard cell row 10b1 (a first standard cell row), switch cell SW1 (a second switch cell) disposed at a position corresponding to at least one of standard cell columns 21 or 22 located at the both ends. For example, in standard cell row 10b1, switch cells SW1 may be arranged at positions corresponding to standard cell columns 21 and 22 located at the both ends.

Accordingly, since switch cells SW1 can be arranged at positions corresponding to standard cell columns 21 and 22 whose voltage is likely to decrease, decrease in the voltage of semiconductor integrated circuit device 1b can be suppressed.

### (Variation 3 of Embodiment)

Hereinafter, a semiconductor integrated circuit device according to the present variation is described with reference to FIG. 7. FIG. 7 is a plan view of the configuration of semiconductor integrated circuit device 1c according to the present variation. It should be noted that, hereinafter, the description will focus on the difference from the embodiment, and the content that is the same as or similar to that of the embodiment is omitted or simplified. Semiconductor integrated circuit device 1c according to the present variation is different from semiconductor integrated circuit device 1 according to the embodiment in that semiconductor integrated circuit device 1c further includes a standard cell row in which a switch cell is disposed at a position corresponding to a standard cell column other than the standard cell columns located at the both ends. Moreover, switch cell SW2 that is included in addition to switch cells SW included in semiconductor integrated circuit device 1 according to the embodiment is hatched differently from switch cells SW and SW3. Switch cell SW3 corresponds to switch cell SW1 according to Variation 2 of the embodiment.

As illustrated in FIG. 7, the plurality of standard cell rows 10 of semiconductor integrated circuit device 1c include standard cell rows 10c1, 10c2, and 10c3 (third standard cell rows) in each of which one or more switch cells SW2 are arranged at one or more positions corresponding to, among the plurality of standard cell columns 20, one or more standard cell columns 23 other than standard cell columns 21 and 22 located at the both ends.

One or more switch cells SW2 are arranged in each of standard cell rows 10c1, 10c2, and 10c3. In each of standard cell rows 10c1, 10c2, and 10c3, no switch cell SW is disposed at positions corresponding to standard cell columns 21 and 22 located at the both ends among the plurality of standard cell columns 20, and one or more switch cells SW2 are arranged at one or more positions that correspond to one or more standard cell columns 23 other than standard cell columns 21 and 22 and are different from the one or more positions of the one or more switch cells SW arranged in each of standard cell rows 10a1 and 10a2.

Each of standard cell rows 10c1 and 10c2 includes one switch cell SW2 at a position corresponding to a different one of standard cell columns 23 other than standard cell columns 21 and 22.

Standard cell row 10c3 includes two switch cells SW2 at positions corresponding to two of standard cell columns 23 other than standard cell columns 21 and 22.

Switch cells SW2 may be arranged at random positions in standard cell rows 10c1, 10c2, and 10c3, for example. Moreover, switch cell SW2 may be disposed next to switch cell SW in the Y direction, for example. The number of switch cells SW2 arranged in each of standard cell rows 10c1, 10c2, and 10c3 may be smaller than the number of switch cells SW arranged in standard cell row 10a3 or 10a4. Switch cell SW2 is an example of one or more switch cells arranged in one or more standard cell columns 23 other than standard cell columns 21 and 22, among the plurality of switch cells SW.

It should be noted that it is sufficient if semiconductor integrated circuit device 1c includes at least one of standard cell rows 10c1, 10c2, or 10c3. For example, in standard cell row 10c, no switch cell SW3 may be disposed at positions corresponding to standard cell columns 21 and 22 located at the both ends among the plurality of standard cell columns 20 and one or more switch cells SW2 may be arranged at one or more positions (e.g., random positions) that correspond to one or more standard cell columns 23 other than standard cell columns 21 and 22 and are different from the one or more positions of one or more switch cells arranged in each of standard cell rows 10a1 and 10a2.

Moreover, semiconductor integrated circuit device 1c may include standard cell rows 10a5, 10a6, and 10b2, and strap power supply wire 33. Each of standard cell rows 10a5, 10a6, and 10b2 includes no switch cell SW2.

Standard cell row 10a5 includes switch cell SW3 disposed at a position corresponding to standard cell column 21, in addition to the configuration of standard cell row 10a1.

Standard cell row 10a6 includes switch cell SW3 disposed at a position corresponding to standard cell column 21, in addition to the configuration of standard cell row 10a2.

Standard cell row 10b2 includes switch cell SW3 disposed at a position corresponding to standard cell column 21, in addition to the configuration of standard cell row 10b.

It should be noted that switch cells SW2 and SW3 control whether to interrupt power supply to respective standard cells 11. Switch cells SW2 and SW3 are arranged at intersections between strap power supply wires 30 and power supply wires L1 in plan view, and each of switch cells SW2 and SW3 is configured to switch between electrical connection and disconnection between strap power supply wire 30 and power supply wire L1 at the intersection at which the switch cell is arranged, according to a control signal. In other words, each of switch cells SW2 and SW3 switches between conduction and non-conduction between strap power supply wire 30 and power supply wire L1 at the intersection at which the switch cell is arranged. Moreover, each of switch cells SW2 and SW3 has the same configuration as switch cell SW. Furthermore, switch cell SW3 may be disposed in at least one of standard cell rows 10c1, 10c2, or 10c3, for example.

Strap power supply wire 33 is disposed in standard cell column 21 so that strap power supply wire 33 extends in the Y direction. Strap power supply wire 33 is, for example, disposed in only standard cell column 21 in which switch cell SW3 is disposed, among standard cell columns 21 and 22 located at the both ends.

As described above, the plurality of standard cell rows 10 included in semiconductor integrated circuit device 1c according to the present variation further include standard cell row 10c1, 10c2, or 10c3 (third standard cell row) in which no switch cell SW3 is disposed at positions corresponding to standard cell columns 21 and 22 located at the both ends among the plurality of standard cell columns 20 and one or more switch cells SW2 among the plurality of switch cells SW are arranged at one or more positions that correspond to one or more standard cell columns 23 other than standard cell columns 21 and 22 and are different from the one or more positions of one or more switch cells in standard cell row 10a1 or 10a2 (second standard cell row).

Thus, one or more switch cells SW2 can be arranged more freely.

### OTHER EMBODIMENTS

Although a semiconductor integrated circuit device according to one or more aspects has been described above based on the embodiment and the like, the present disclosure is not limited to the embodiment and the like. Various modifications of the embodiment as well as embodiments resulting from arbitrary combinations of constituent elements of the embodiment that may be conceived by those skilled in the art may be included within the scope of the present disclosure as long as they do not depart from the essence of the present disclosure.

For example, although an example in which arrangement positions of the plurality of switch cells in the second direction are different between adjacent strap power supply wires (e.g., a first strap power supply wire and a second strap power supply wire) has been described in the above-described embodiment and the like, the present disclosure is not limited to this example, and part or all of arrangement positions of the plurality of switch cells in the second direction may be the same between the adjacent strap power supply wires, for example. Moreover, although an example in which arrangement positions of the plurality of switch cells in the first direction are different between adjacent standard cell rows (e.g., a fourth standard cell row and a fifth standard cell row) has been described, the present disclosure is not limited to this example, and part or all of arrangement positions of the plurality of switch cells in the first direction may be the same between the adjacent standard cell rows, for example.

Furthermore, a power interruption method using a switch cell according to the above-described embodiment and the like may be a method of cutting off a power supply potential (VDD) or a method of cutting off a ground potential (VSS).

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is applicable to a semiconductor integrated circuit device using a power interruption technique.

1. A semiconductor integrated circuit device comprising:
a plurality of standard cell rows each of which includes a plurality of standard cells that are arranged in a first direction and a power supply wire that extends in the first direction and supplies power to the plurality of standard cells;
a plurality of strap power supply wires that extend in a second direction above a plurality of power supply wires each of which is the power supply wire, the second direction being orthogonal to the first direction;
a plurality of supplementary strap power supply wires that extend in the second direction above the plurality of power supply wires and are each connected to each of the plurality of power supply wires; and
a plurality of first switch cells arranged at intersections between the plurality of strap power supply wires and the plurality of power supply wires, each of the plurality of first switch cells being configured to switch between electrical connection and disconnection between the strap power supply wire and the power supply wire at the intersection at which the first switch cell is arranged, according to a control signal, wherein
the plurality of standard cell rows are arranged in the second direction to form a plurality of standard cell columns, and
the plurality of standard cell rows include a first standard cell row in which none of the plurality of first switch cells are arranged at one or more positions corresponding to, among the plurality of standard cell columns, one or more standard cell columns other than standard cell columns located at both ends of the plurality of standard cell columns.

2. The semiconductor integrated circuit device according to claim 1, wherein
in the first standard cell row, none of the plurality of first switch cells are arranged at positions corresponding to the standard cell columns located at the both ends.

3. The semiconductor integrated circuit device according to claim 1, further comprising:
in the first standard cell row, a second switch cell that is disposed at at least one of positions corresponding to the standard cell columns located at the both ends.

4. The semiconductor integrated circuit device according to claim 3, wherein
in the first standard cell row, second switch cells are arranged at the positions corresponding to the standard cell columns located at the both ends, the second switch cells each being the second switch cell.

5. The semiconductor integrated circuit device according to claim 1, wherein
the first standard cell row is supplied with power through any one of the plurality of supplementary strap power supply wires.

6. The semiconductor integrated circuit device according to claim 1, wherein
the plurality of standard cell rows further include a second standard cell row in which one or more first switch cells among the plurality of first switch cells are arranged at one or more positions corresponding to the one or more standard cell columns among the plurality of standard cell columns, and
the plurality of supplementary strap power supply wires are each connected to each of power supply wires arranged in the first standard cell row and the second standard cell row among the plurality of power supply wires.

7. The semiconductor integrated circuit device according to claim 1, wherein
the plurality of strap power supply wires include a first strap power supply wire and a second strap power supply wire that are adjacent to each other, and
the plurality of first switch cells have arrangement positions in the second direction that are different between the first strap power supply wire and the second strap power supply wire.

8. The semiconductor integrated circuit device according to claim 1, wherein
arrangement positions of the plurality of first switch cells in the first direction are same for every M strap power supply wires among the plurality of strap power supply wires, M being a natural number greater than or equal to 2.

9. The semiconductor integrated circuit device according to claim 6, wherein
the plurality of standard cell rows further include a third standard cell row in which none of the plurality of first switch cells are arranged at positions corresponding to the standard cell columns located at the both ends among the plurality of standard cell columns and an other one or more first switch cells among the plurality of first switch cells are arranged at one or more positions that correspond to the one or more standard cell columns other than the standard cell columns located at the both ends among the plurality of standard cell columns and are different from the one or more positions of the one or more first switch cells arranged in the second standard cell row.

10. The semiconductor integrated circuit device according to claim 1, wherein
the plurality of standard cell rows further include a fourth standard cell row and a fifth standard cell row in each of which different one or more first switch cells among the plurality of first switch cells are arranged, the fourth standard cell row and the fifth standard cell row being adjacent to each other, and
the one or more first switch cells arranged in the fourth standard cell row and the one or more first switch cells arranged in the fifth standard cell row are different from each other in arrangement position in the first direction.

11. The semiconductor integrated circuit device according to claim 1, wherein
arrangement positions of the plurality of first switch cells in the second direction are same for every N standard cell rows including the first standard cell row among the plurality of standard cell rows, N being a natural number greater than or equal to 2.
